(19) United States
(12) Patent Application Publication
(10) Pub. No.: US 2023/0053562 A1
(43) Pub. Date: Feb. 23, 2023

(54) HYDROPHOBIC MEDIA FOR THE COLLECTION OF MINERAL PARTICLES IN AQUEOUS SYSTEMS

(71) Applicants: CiDRA CORPORATE SERVICES LLC, Wallingford, CT (US); BYK-CHEMIE GMBH, Wesel (DE)

(72) Inventors: Michael Stephen RYAN, Newtown, CT (US); Jeff GELORME, Burlington, CT (US); Jordi Calveras IBANEZ, Agawam, MA (US); Allison K. GREENE, West Hartford, CT (US); Michael D. COPPOLA, Trumbull, CT (US); Guozhen YANG, Middletown, CT (US); Kathryn SACKINGER, New Haven, CT (US)

(21) Appl. No.: 17/795,932

(22) PCT Filed: Feb. 4, 2021
(86) PCT No.: PCT/US2021/016546

§ 371 Date: Jul. 28, 2022

Related U.S. Application Data
(60) Provisional application No. 62/970,820, filed on Feb. 6, 2020.

(51) Int. Cl. B03D 1/02; B01D 39/16; C23C 16/455; C23C 16/40; C23C 16/56; B03D 1/018; C09D 5/00; C09D 183/04; C08J 9/36

(52) U.S. Cl. CPC B03D 1/023; B01D 39/1669; B03D 1/018; C08J 9/365; C09D 5/002; C09D 183/04; C23C 16/40; C23C 16/56; C23C 16/45555; B01D 2239/065; B01D 2239/0428; B01D 2239/0478; B03D 2201/02; C08J 2483/04

(57) ABSTRACT

A composite medium for collecting mineral particles in an aqueous slurry has a polymer substrate deposited or penetrated with an inorganic material and further coated with a hydrophobic material. The hydrophobic material can be a hydrophobic silane or a hydrophobic polymer such as polysiloxane. Alternatively, the inorganic material deposited substrate is first reacted with a reactive silane and then coated with a hydrophobic polymer. The polymer substrate can be in the form of a spherical bead, a small cube, a filter or a conveyor.

### CROSS REFERENCE TO RELATED APPLICATION

This application claims the benefit of U.S. Provisional Application No. 62/970,820 (712-2.465-1 (CCS-0213)), filed 6 Feb. 2020, which is incorporated by reference herein in its entirety.

### BACKGROUND OF THE INVENTION

### 1. Technical Field

The present invention relates generally to techniques for separating valuable material from unwanted material in a mixture, such as a pulp slurry; and more particularly, relates to a collection medium for attracting mineral particles of interest in the pulp slurry and to an apparatus, e.g., where collection media are caused to contact the pulp slurry and attract mineral particles of interest therein.

### 2. Description of Related Art

In many industrial processes, flotation is used to separate valuable or desired material from unwanted material. By way of example, in this process a mixture of water, valuable material, unwanted material, chemicals and air is placed into a flotation cell. The chemicals are used to make the desired material hydrophobic and the air is used to carry the hydrophobic material to the surface of the flotation cell. When the hydrophobic material and air bubbles collide they become attached to each other. The air bubbles rise to the surface carrying the desired material attached thereto.

The performance of the flotation cell is dependent on the air bubble surface area flux and air bubble size distribution in the collection zone of the cell. The air bubble surface area flux is dependent on the size of the bubbles and the air injection rate. Controlling the air bubble surface area flux has traditionally been very difficult. There is a need in the industry to provide a better way to separate valuable material from unwanted material, e.g., including in such a flotation cell, so as to eliminate problems associated with using air bubbles in such a separation process.

Synthetic beads and polymeric conveyor belts coated with a hydrophobic material have been used to attract mineral particles in an aqueous slurry. In general, the hydrophobic coating on the synthetic beads or conveyor belt may be made of low surface energy polymeric materials. However, low surface energy polymeric coatings are difficult to adhere to the synthetic beads or polymeric conveyor belts. As a result, the coatings may not be durable.

In addition, the prior art techniques are limited in the scope and the provisioning of effective durable coatings useful for hydrophobic particle collection. By way of example, see US 9,327,294; US 9,352,335; as well as US 2017/01664556, which disclose such prior art techniques.

### SUMMARY OF THE INVENTION

### The Basic Invention

In general, the present invention provides a new and unique composite medium to be used as a collection surface for attracting mineral particles of interest in an aqueous system. The composite medium may include, or be formed by, a polymer substrate applied with an inorganic material, and then coated with a hydrophobic material. The composite medium may be arranged to contact a slurry in a flotation cell, an agitating tank or a tumbler to collect mineral particles of interest.

According to some embodiments, the inorganic material may be applied to a polymeric substrate, e.g., such as a foam including an open-cell foam, and then it may be reacted with a hydrophobic silane to provide a durable hydrophobic coating onto the surface of a substrate for the purpose of collecting hydrophobic particles in an aqueous system.

The inorganic material may be deposited using atomic layer deposition (ALD), molecular layer deposition (MLD), sequential infiltration synthesis (SIS), or via a penetrating solvent. The inorganic material may consist of metal oxide such as TiO2, Al2O3, ZnO, MgO, SiO2, HfO2, ZrO2, or a precursor that may be oxidized to such forms such as diethyl zinc, trimethylaluminum, or the like. Subsequent to the deposition/infiltration of the inorganic species, it may be further reacted with a silane such as (3-aminopropyl) triethoxysilane (APTS), butyldimethyl (dimethylamino) silane (BDMS) or the like. This provides a covalently bonded, durable, hydrophobic coating to the substrate.

This composite media may then be used for the purpose of attracting hydrophobic particles in aqueous systems.

According to some embodiments, this composite media may be further reacted through use of a reactive silane, for example with vinyl functionality such as vinyl alkoxy silane, vinyl acetoxy silane and the like; that may then be further reacted with a polymeric coating. This composite media may include a polymeric substrate such as a foam with an inorganic deposition/ penetration, reacted with a functional silane, and then further reacted with a polymeric coating that covalently bonds to the functional silane. The polymeric coating may be a polysiloxane.

Alternatively, and according to some embodiments, the polymeric coating may be directly applied to the substrate with the inorganic deposition/penetration such that the polymeric coating directly reacts to the inorganic species.

The bonded hydrophobic silane coating without the polymeric top layer may be receptive to fine hydrophobic particles in aqueous systems. It may also provide a low-energy surface receptive to a hydrophobic polymeric top layer such as a PDMS due to effective wetting of the PDMS on the modified surface. When the silane is functional, such as with vinyl functionality, it provides a reactive surface for the reactive PDMS to covalently bond to. The inorganic surface alone provides a functional surface for coating with either a silane or reactive polysiloxane.

During the mineral extraction process, the coated substrate must contact the aqueous slurry, be removed from the slurry, and then the hydrophobic particles removed from the coated substrate to recover the valuable particles. This contact could occur within the flotation cell, the agitated tank, the tumbler or some other such known method of contact. The particle-rich coated substrate is then removed from the contactor and washed and/or blown to remove unwanted, unadhered hydrophobic particles. The hydrophobic particles are then removed from the coated surface and further concentrated for recovery.

Hydrophobic particles of interest may include but not be limited to hydrophobic and/or hydrophobized metallic or nonmetallic mineral particles, coal particles, diamond particles, or any hydrophobic particles of value.

### The Composite Medium/Media

In particular, and by way of example, the present invention may include, or take the form of, a composite medium having a combination of:
a polymeric substrate;
an inorganic material disposed on the polymeric substrate to form an inorganic deposited substrate; and
a hydrophobic coating that is disposed on and reacts with the inorganic material of the inorganic deposited substrate so as to form a covalently bonded collection surface for attracting mineral particles of interest in an aqueous system.

According to some embodiments, the composite medium may also include one or more of the following features:

The hydrophobic coating may include, and be formed by, a hydrophobic silane that is applied to and reacts with the inorganic material.

The hydrophobic silane may be selected from (3-aminopropyl) triethoxysilane (APTS) or butyldimethyl (dimethylamino) silane (BDMS).

The hydrophobic coating may include, and be formed by, a polymeric coating that is applied to and reacts with the inorganic material. The polymeric coating may include a hydrophobic silicone polymer. The hydrophobic silicone polymer may include polysiloxane.

The hydrophobic coating may include, and be formed by, a combination of a reactive silane that is applied to and reacts with the inorganic material, and a polymeric coating that is subsequently applied to and reacts with the reactive silane and the inorganic material. The reactive silane may be selected from vinyl alkoxy silane or vinyl acetoxy silane.

The hydrophobic coating may include, and be formed by, a combination of a hydrophobic silane that is applied to and reacts with the inorganic material, a reactive silane that is subsequently applied to and reacts with the hydrophobic silane and the inorganic material, and a polymeric coating that is subsequently applied to and reacts with the hydrophobic silane, the reactive silane and the inorganic material.

The inorganic material may include a metal oxide, e.g., that is selected from TiO2, Al2O3, ZnO, MgO, SiO2, HfO2 and ZrO2.

The inorganic material may include an oxidized precursor selected from diethyl zinc or trimethylaluminum.

The inorganic material may be deposited using an atomic layer deposition (ALD), a molecular layer deposition (MLD), a sequential infiltration synthesis (SIS), or via a penetrating solvent.

The polymeric substrate may include, or take the form of, a bead, or a filter, or a a conveyor belt.

The polymeric substrate may be made of a polymer selected from a group consisting of polyamides, polyesters, polyurethanes, phenol-formaldehyde, ureaformaldehyde, melamine-formaldehyde, polyacetal, polyethylene, polyisobutylene, polyacrylonitrile, poly(vinyl chloride), polystyrene, poly(methyl methacrylates), poly(vinyl acetate), poly(vinylidene chloride), polyisoprene, polybutadiene, polyacrylates, poly(carbonate), and phenolic resin.

### The Apparatus

According to some embodiment, the present invention may include, or take the form of, an apparatus, featuring a combination of a loading stage, a mixing mechanism and a releasing stage.

The loading stage has an input configured to receive an aqueous slurry containing mineral particles and unwanted materials, and also has a plurality of composite media. The composite media has a polymeric substrate, an inorganic material disposed on the polymeric substrate, forming an inorganic material deposited substrate, and a hydrophobic coating that is disposed on and reacts with the inorganic material of the inorganic deposited substrate so as to form a covalently bonded collection surface for attracting mineral particles of interest in an aqueous system.

The mixing mechanism is configured to cause the composite media to contact with the aqueous slurry for providing loaded media to the releasing stage, the loaded media comprising the composite media having the mineral particles attached thereon.

The releasing stage has a removing mechanism configured to remove the mineral particles from the loaded media.

According to some embodiments, the method may also include one or more of the features set forth herein, e.g., including the following:

The loaded media further may include unwanted material attached to the composite media, the apparatus also having a cleaning stage configured to remove the unwanted material from the loaded media.

The hydrophobic material may include a hydrophobic silicone polymer or a hydrophobic silane.

### The Method

According to some embodiment, the present invention may include, or take the form of, a method for making a composite medium for attracting mineral particles of interest in an aqueous system, featuring:
providing a polymeric substrate;
disposing an inorganic material on the polymeric substrate to form an inorganic deposited substrate, and
depositing a hydrophobic coating on the inorganic material of the inorganic deposited substrate that reacts with the inorganic material so as to form a covalently bonded collection surface for attracting mineral particles of interest in an aqueous system.

According to some embodiments, the method may also include one or more of the features set forth herein.

### BRIEF DESCRIPTION OF THE DRAWING

The drawing includes FIG. 1A to 6, which are briefly described as follows:

FIG. 1A illustrates a composite medium, according to an embodiment of the present invention.

FIG. 1B illustrates another composite medium, according to an embodiment of the present invention.

FIG. 1C illustrates a different composite medium, according to an embodiment of the present invention.

FIG. 1D illustrates yet another composite medium, according to an embodiment of the present invention.

FIG. 2 illustrates a synthetic bead used as the polymeric substrate in the composite medium, according to an embodiment of the present invention.

FIG. 3 illustrates a piece of foam used as the polymeric substrate in the composite medium, according to an embodiment of the present invention.

FIG. 4 illustrates a filter used as the polymeric substrate in the composite medium, according to an embodiment of the present invention.

FIG. 5 illustrates a conveyor belt used as the polymeric substrate in the composite medium, according to an embodiment of the present invention.

FIG. 6 illustrates an apparatus having one or more composite media to collect mineral particles in an aqueous slurry, according to an embodiment of the present invention.

### DETAILED DESCRIPTION OF THE BEST MODE OF THE INVENTION

The present invention is described in detailed in relation to the drawing, as follows:

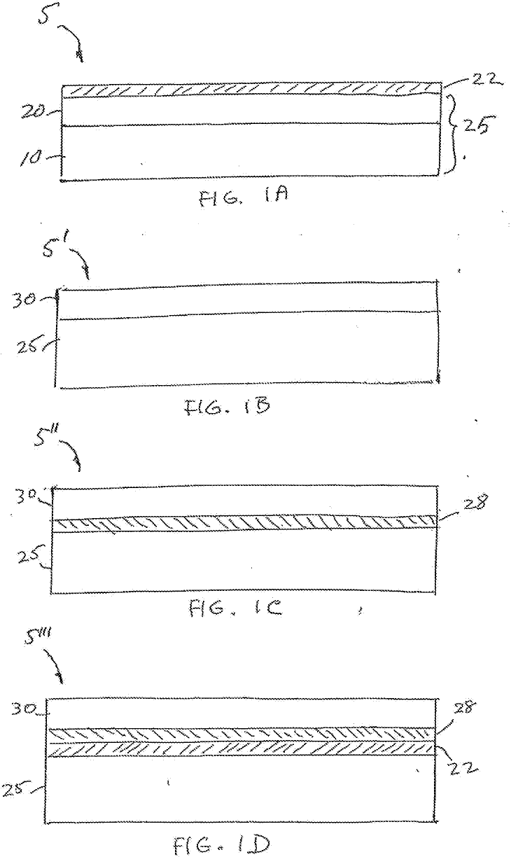

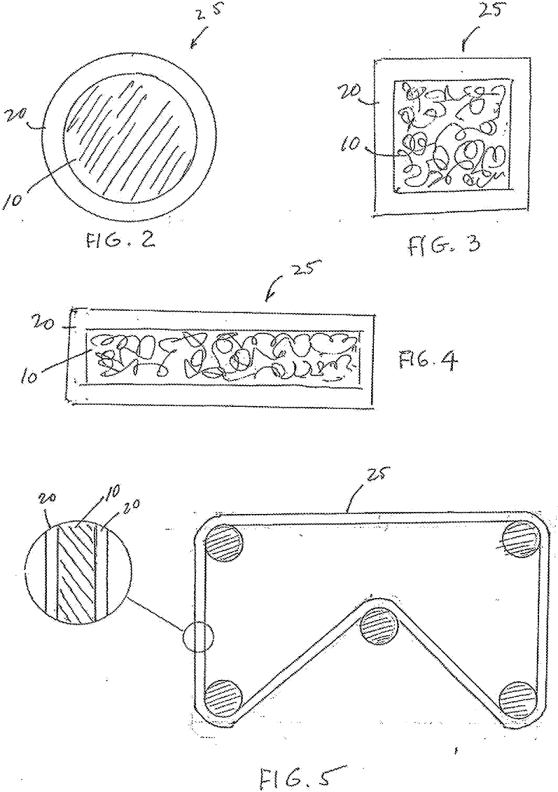

### Figure 1A: The Composite Media 5

According to some embodiment of the present invention, and consistent with that shown in FIG. 1A, a composite medium 5 may be formed using a process that includes applying/depositing an inorganic material 20 to a polymeric substrate 10 (e.g., such as a foam, including an open-cell foam), and then depositing a hydrophobic silane 22 onto the inorganic material 20 that is applied to and reacts with the inorganic material 20 to provide a durable hydrophobic coating onto the surface of the polymeric substrate 10 for the purpose of collecting hydrophobic particles in an aqueous system.

By way of example, the inorganic material 20 may be deposited using an atomic layer deposition (ALD), a molecular layer deposition (MLD), a sequential infiltration synthesis (SIS), or via a penetrating solvent, which are all processes that are known in the art. By way of further example, the inorganic material 20 may consist of a metal oxide such as TiO2, Al2O3, ZnO, MgO, SiO2, HfO2, ZrO2, or a precursor that may be oxidized to such forms such as diethyl zinc, trimethylaluminum, or the like. Subsequent to the deposition/infiltration of the inorganic species, the inorganic deposited substrate 25 may be further reacted with the hydrophobic silane 22, e.g. such as (3-aminopropyl) triethoxysilane (APTS), butyldimethyl (dimethylamino) silane (BDMS), or the like, which provides and forms a covalently bonded, durable, hydrophobic coating onto the polymeric substrate 10.

This composite medium 5 may then be used for the purpose of attracting hydrophobic particles in aqueous systems, e.g., consistent with that set forth herein.

In FIG. 1A, the bonded hydrophobic silane coating without any polymeric top layer may be receptive to fine hydrophobic particles in aqueous systems. It may also provide a low-energy surface receptive to a hydrophobic polymeric top layer such as a PDMS due to effective wetting of the PDMS on the modified surface, e.g., consistent with that described herein. When the silane is functional, such as with vinyl functionality, it provides a reactive surface for the reactive PDMS to covalently bond to. In effect, the inorganic surface alone provides a functional surface for coating with either a silane or reactive polysiloxane, as also described herein.

The composite medium 5 having a coated substrate shown in FIG. 1A must contact the aqueous slurry, be removed from the aqueous slurry, and then the hydrophobic particles removed from the coated substrate to recover the valuable particles. By way of example, this contact may occur within a flotation cell, an agitated tank, a tumbler, or some other such method of contact, e.g., either now known or later developed in the future. The particle-rich coated substrate is then removed from the contactor and washed and/or blown to remove unwanted, unadhered hydrophobic particles. The hydrophobic particles are then removed from the coated surface and further concentrated for recovery.

Hydrophobic particles of interest may include but not be limited to hydrophobic and/or hydrophobized metallic or nonmetallic mineral particles, coal particles, diamond particles, or any hydrophobic particles of value. By way of example, the metallic mineral particles may include copper mineral particles.

### Figures 1B Thru 1D: Other Composite Medium 5', 5", 5"'

Alternatively, according to some embodiment of the present invention, and as shown in FIG. 1B, the present invention may include a composite medium 5' having a polymeric coating 30 applied thereto, so as to produce a reactive layered combination of the inorganic deposited substrate 25 and the polymeric coating 30. In FIG. 1B, the polymeric coating 30 may be applied to and react with the inorganic material 20 of the inorganic deposited substrate 25 so as to form the composite medium 5'. By way of example, the polymeric coating 30 may be directly applied to the inorganic deposited substrate 25 with an inorganic deposition/penetration such that the polymeric coating 30 directly reacts to the inorganic species of the inorganic deposited substrate 25. By way of further example, the polymeric coating 30 may be a polysiloxane.

Further, according to some embodiment of the present invention, and as shown in FIG. 1C, the present invention may include a composite medium 5" formed by applying a combination of a reactive silane 28 and the polymeric coating 30, so as to produce a reactive layered combination that includes the inorganic deposited substrate 25, the reactive silane 28 and the polymeric coating 30. In FIG. 1C, the reactive silane 28 may be applied to and react with the inorganic material 20 of the inorganic material deposited substrate, and then the polymeric coating 30 may be applied to and react with the reactive silane 28 so as to form the composite medium 5". The reactive silane 28 may have vinyl functionality, and may include a vinyl alkoxy silane, a vinyl acetoxy silane and the like, e.g., that may be further reacted with the polymeric coating. This composite medium 5 may the polymeric substrate 10, e.g. that may include a foam with an inorganic deposition/penetration, reacted with a functional silane, and then may be further reacted with a polymeric coating that covalently bonds to the functional silane. By way of example, the polymeric coating may be a polysiloxane.

Furthermore, according to some embodiment of the present invention, as shown in FIG. 1D, the present invention may include a composite medium 5"' formed by applying a combination of the hydrophobic silane 22, the reactive silane 28 and the polymeric coating 30, so as to produce a reactive layered combination of the inorganic deposited substrate 25, the hydrophobic silane 22, the reactive silane 28 and the polymeric coating 30. In FIG. 1D, the hydrophobic silane 22 may be applied to and react with the inorganic material 20 of the inorganic deposited substrate 25, then the reactive silane 28 may be applied to and react with the hydrophobic silane 22, and then the polymeric coating 30 may be applied to and react with the reactive silane 28 so as to form the composite medium 5"'. The inorganic material 20, the hydrophobic silane 22, the reactive silane 28 and the polymeric coating 30 may include, or take the form of, the examples set forth herein,.

### Figures 2-5: Different Shapes and Form of the Composite Medium

As shown in FIGS. 1A-1D, the polymeric substrate 10 may be configured in different shapes and forms. As shown in FIG. 2, the polymeric substrate 10 of the composite medium 5, 5' 5" or 5"' may include, or take the form of, e.g., a bead, such as a spherical bead with a solid body made of polymer, or a hollow shell made of polymer, or a bead made of glass, ceramic or metal with a polymer surface coating. According to some embodiments of the present invention, the polymer may be selected from a group consisting of polyamides, polyesters, polyurethanes, phenol-formaldehyde, urea-formaldehyde, melamine-formaldehyde, polyacetal, polyethylene, polyisobutylene, polyacrylonitrile, poly(vinyl chloride), polystyrene, poly(methyl methacrylates), poly(vinyl acetate), poly(vinylidene chloride), polyisoprene, polybutadiene, polyacrylates, poly(carbonate), and phenolic resin.

When the density of the beads is less than that of the aqueous slurry, the beads can be arranged or configured to rise from a lower portion of a flotation cell to a top portion so as to increase the contact with the hydrophobic particles in the slurry. As the beads rise, they attract mineral particles of interest, are likely to become loaded media, and can then be skimmed off from the top of the flotation cell for further processing, e.g., as described below.

As shown in FIG. 3, the polymeric substrate may be a piece of foam, such as reticulated foam having a 3D open-cell structure. The foam can be made of any of the polymers listed above and herein. In particular, the foam can be made of a soft polymer such as polyurethane or polyisoprene. Ideally, all six outer surfaces of the foam piece can be deposited or penetrated with the inorganic material and further coated with a hydrophobic material as as hydrophobic silane or hydrophobic polymer. The hydrophobic polymer may be hydrophobic silicone polymer including polysiloxanates and poly(dimethylsiloxane) also known as PDMS. The foam pieces with hydrophobic surfaces may be arranged in a rotating drum or tumbler to interact with the mineral particles in the slurry to become loaded media.

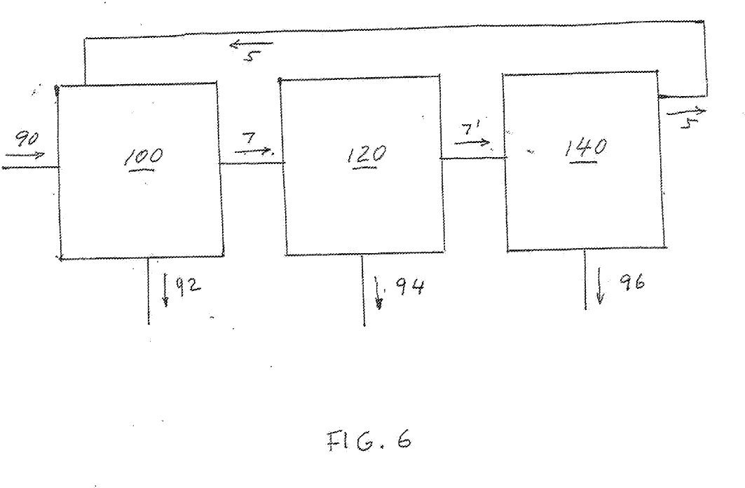

As shown in FIG. 4, the polymer substrate may include, or take the form of, a filter to allow the aqueous slurry to flow through. The filter can be made of a foam-like material deposited or penetrated with an inorganic material and further reacted with a hydrophobic material.

As shown in FIG. 5, the polymer substrate may include, or take the form of, a conveyor belt. The conveyor belt may be arranged to move through the aqueous slurry to collect mineral particles in a loading stage and then move through a releasing stage where the collected mineral particles are removed from the conveyor belt with a chemical or a mechanical means. A section of the conveyor belt is enlarged to show the polymeric substrate 10 deposited or penetrated with the inorganic material 20 to form the inorganic material deposited substrate 25. The substrate 25 is further coated with a hydrophobic material such as hydrophobic silane 22 or hydrophobic polymer 30, e.g., as shown in FIGS. 1A, 1B and 1C.

By way of example, see U.S. Pat. Nos. 9,731,221; 10,751,693; 10,774,400; and 10,807,105, which disclose mineral processing techniques using synthetic beads, reticulated foam and conveyor belts, which are all incorporated by reference in their entirety.

### Figure 6

As described above, the hydrophobically-coated, inorganic material deposited substrate or composite medium is arranged to contact with the aqueous slurry, to be removed from the slurry, and then the hydrophobic particles are removed from the loaded medium. The hydrophobic particles may include unwanted material and valuable particles. This contact may occur within a flotation cell, an agitated tank, a tumbler, or some other such method of contact, e.g., either now known or later developed in the future. The particle-rich coated substrate or loaded medium is then removed from the contactor and washed and/or blown to remove unwanted, unadhered hydrophobic particles. The valuable particles are then removed from the coated surface and further concentrated for recovery.

By way of example, FIG. 6 illustrates an apparatus for collecting mineral or valuable particles in an aqueous slurry, e.g., which may include three stages: a loading stage 100, a cleaning stage 120 and a releasing stage 140.

The loading stage 100 is configured to receive an aqueous slurry 90. By way of example, the loading stage 100 may be a flotation cell, a tumbler or an agitating tank where the composite media 5, 5', 5", 5"' are arranged to contact with the aqueous slurry in order to collect mineral particles in the aqueous slurry. The part of the aqueous slurry in which most of the valuable particles have been collected is discharged from the loading stage as tails 92. The loaded media 7 (i.e., the composite media having valuable particles and unwanted material attached thereto) are transferred to the cleaning stage 120.

The cleaning stage 120 washes the unwanted material off the loaded media 7, and discharges unwanted material 94 from the cleaning stage 120. After cleaning, the loaded media 7' are transferred to the releasing stage 140.

The releasing stage 140 removes the valuable particles from the composite media, discharges the valuable particles as concentrate 96, and recycles the recovered composite media 5 back to the loading stage 100 for further processing.

### The Scope of the Invention

It should be appreciated that any of the features, characteristics, alternatives or modifications described regarding a particular embodiment herein may also be applied, used, or incorporated with any other embodiment described herein. The bead as shown in FIG. 2, for example, can be made from a magnetic polymer or have a magnetic core so that the para-, ferri-, ferro-magnetism of the composite media is greater than the para-, ferri-, ferro-magnetism of the unwanted ground ore particles in the slurry. Thus, although the invention has been described and illustrated with respect to exemplary embodiments thereof, the foregoing and various other additions and omissions may be made therein and thereto without departing from the scope of the present invention.

What is claimed is:

1. A composite medium, comprising:
a polymeric substrate;
an inorganic material disposed on the polymeric substrate to form an inorganic deposited substrate, and
a hydrophobic coating that is disposed on and reacts with the inorganic material of the inorganic deposited substrate so as to form a covalently bonded collection surface for attracting mineral particles of interest in an aqueous system.

2. The composite medium according to claim 1, wherein the hydrophobic coating includes, and is formed by, a hydrophobic silane that is applied to and reacts with the inorganic material.

3. The composite medium according to claim 2, wherein the hydrophobic silane is selected from (3-aminopropyl) triethoxysilane (APTS) or butyldimethyl (dimethylamino) silane (BDMS).

4. The composite medium according to claim 1, wherein the hydrophobic coating includes, and is formed by, a polymeric coating that is applied to and reacts with the inorganic material.

5. The composite medium according to claim 4, wherein the polymeric coating comprises a hydrophobic silicone polymer.

6. The composite medium according to claim 5, wherein the hydrophobic silicone polymer comprises polysiloxane.

7. The composite medium according to claim 1, wherein the hydrophobic coating includes, and is formed by, a combination of a reactive silane that is applied to and reacts with the inorganic material, and a polymeric coating that is subsequently applied to and reacts with the reactive silane and the inorganic material..

8. The composite medium according to claim 7, wherein the reactive silane is selected from vinyl alkoxy silane or vinyl acetoxy silane.

9. The composite medium according to claim 1, wherein the hydrophobic coating includes, and is formed by, a combination of a hydrophobic silane that is applied to and reacts with the inorganic material, a reactive silane that is subsequently applied to and reacts with the hydrophobic silane and the inorganic material, and a polymeric coating that is subsequently applied to and reacts with the hydrophobic silane, the reactive silane and the inorganic material.

10. The composite medium according to claim 1, wherein the polymeric substrate comprises a reticulated foam having a 3D open-cell structure.

11. The composite medium according to claim 1, wherein the inorganic material comprises a metal oxide.

12. The composite medium according to claim 11, wherein the metal oxide is selected from TiO2, AI2O3, ZnO, MgO, SiO2, HfO2 and ZrO2.

13. The composite medium according to claim 1, wherein the inorganic material comprises an oxidized precursor selected from diethyl zinc or trimethylaluminum.

14. The composite medium according to claim 1, wherein the inorganic material is deposited using an atomic layer deposition (ALD), a molecular layer deposition (MLD), a sequential infiltration synthesis (SIS), or via a penetrating solvent.

15. The composite medium according to claim 1, wherein the polymeric substrate comprises a polymer bead.

16. The composite medium according to claim 1, wherein the polymeric substrate comprises a polymer filter.

17. The composite medium according to claim 1, wherein the polymeric substrate comprises a conveyor belt.

18. The composite medium according to claim 1, wherein the polymeric substrate is made of a polymer selected from a group consisting of polyamides, polyesters, polyurethanes, phenol-formaldehyde, urea-formaldehyde, melamine-formaldehyde, polyacetal, polyethylene, polyisobutylene, polyacrylonitrile, poly(vinyl chloride), polystyrene, poly(methyl methacrylates), poly(vinyl acetate), poly(vinylidene chloride), polyisoprene, polybutadiene, polyacrylates, poly(carbonate), and phenolic resin.

19. An apparatus , comprising:
a loading stage having an input configured to receive an aqueous slurry containing mineral particles and unwanted materials, and also having a plurality of composite media, the composite media having a polymeric substrate, an inorganic material disposed on the polymeric substrate, forming an inorganic material deposited substrate, and a hydrophobic coating that is disposed on and reacts with the inorganic material of the inorganic deposited substrate so as to form a covalently bonded collection surface for attracting mineral particles of interest in an aqueous system;
a mixing mechanism to cause the composite media to contact with the slurry for providing loaded media to the releasing stage, the loaded media comprising the composite media having the mineral particles attached thereon; and
a releasing stage having a removing mechanism configured to remove the mineral particles from the loaded media.

20. The apparatus according to claim 19, wherein the loaded media further comprise unwanted material attached to the composite media, said apparatus further comprising a cleaning stage configured to remove the unwanted material from the loaded media.

21. The apparatus according to claim 19, wherein the hydrophobic coating comprises a hydrophobic silicone polymer or a hydrophobic silane.

22. A method for making a composite medium for attracting mineral particles of interest in an aqueous system, comprising:
providing a polymeric substrate;
disposing an inorganic material on the polymeric substrate to form an inorganic deposited substrate, and
depositing a hydrophobic coating on the inorganic material of the inorganic deposited substrate that reacts with the inorganic material so as to form a covalently bonded collection surface for attracting mineral particles of interest in an aqueous system.
